(19) United States
(12) Patent Application Publication
(10) Pub. No.: US 2026/0112848 A1
(43) Pub. Date: Apr. 23, 2026

(54) TERMINAL CONNECTOR AND ELECTRIC DRIVE ASSEMBLY

(71) Applicant: Lanto Electronic Limited, Kunshan City (CN)

(72) Inventors: Dongchang Fan, Kunshan City (CN); Yi Zhou, Kunshan City (CN); Yanlei Yang, Kunshan City (CN); Tao Zhu, Kunshan City (CN)

(73) Assignee: Lanto Electronic Limited, Kunshan City (CN)

(21) Appl. No.: 19/358,869

(22) Filed: Oct. 15, 2025

(30) Foreign Application Priority Data
Oct. 18, 2024 (CN) 202411463473.5

(51) Int. Cl. H01R 13/66; H01F 1/147; H01R 9/24; H01R 13/504; H01R 13/533

(52) U.S. Cl. CPC H01R 13/6683; H01F 1/14766; H01R 9/24; H01R 13/504; H01R 13/533; H01R 2201/26

(57) ABSTRACT

A terminal connector and an electric drive assembly, includes a terminal block and magnetic conductors arranged on a mounting part. The terminal block has a plurality of connecting terminals for transmitting three-phase electricity, and first connecting ends and second connecting ends of the connecting terminals extend out of the mounting part, so as to be electrically connected to a motor controller and a drive motor respectively. Therefore, the connecting terminals pass through a first coupling space of the magnetic conductor, so that an induced magnetic field generated by the connecting terminals is coupled to the magnetic conductor. At the same time, a second coupling space is arranged on an outer side of the mounting part, so that when the terminal connector is connected to the motor controller, the induction element may be arranged on an inner side of the second coupling space.

### CLAIM OF PRIORITY AND CROSS-REFERENCE TO RELATED APPLICATIONS

This application claims the benefit of Chinese Patent Application No. 202411463473.5, filed on Oct. 18, 2024, which is incorporated herein by reference in its entirety.

### BACKGROUND OF THE DISCLOSURE

### 1. Field of the Disclosure

The present disclosure relates to the field of electric vehicles, and particularly to a terminal connector and an electric drive assembly.

### 2. Description of the Related Art

Three-phase alternating current is a form of power transmission, referred to as three-phase electricity for short. The motor controller of an electric vehicle supplies power to the drive motor through a three-phase terminal block. The three-phase terminal block is provided with three terminals for transmitting three-phase electricity. Effective monitoring of the current on the terminals may ensure the driving performance of the motor controller on the drive motor. How to facilitate the monitoring of the current on the terminals and simplify the installation structure of the electric drive assembly has become a problem to be solved.

### BRIEF DESCRIPTION OF THE DISCLOSURE

In view of this, embodiments of the present disclosure provide a terminal connector and an electric drive assembly. Magnetic conductors and a terminal block are arranged on a mounting part together, and a connecting terminal pass through a first coupling space, so that a cooperation between a second coupling space and an induction element arranged therein is utilized, an installation structure of the electric drive assembly is simplified, and a current monitoring is facilitated.

According to a first aspect of the embodiments of the present disclosure, a terminal connector is provided. The terminal connector comprises: a mounting part; a terminal block arranged on the mounting part and including a plurality of connecting terminals, wherein each connecting terminal includes a first connecting end and a second connecting end; and a plurality of magnetic conductors arranged on the mounting part at intervals and in one-to-one correspondence with the plurality of connecting terminals, wherein each magnetic conductor has a first coupling space and a second coupling space, the connecting terminal passes through a corresponding first coupling space, the first connecting end and the second connecting end respectively extend out of the mounting part, and a plurality of second coupling spaces are arranged at intervals and located on an outer side of the mounting part; wherein an induced magnetic field generated by the connecting terminal acts on the second coupling space through the first coupling space.

In a second aspect, the embodiment of the present disclosure further provides an electric drive assembly. The electric drive assembly comprises: a drive motor; a motor controller including a power assembly, wherein the power assembly includes a circuit board and a plurality of induction elements arranged on the circuit board; and a terminal connector including a mounting part, a terminal block and a plurality of magnetic conductors, the terminal block being arranged on the mounting part and including a plurality of connecting terminals, each connecting terminal including a first connecting end and a second connecting end, the plurality of magnetic conductors being arranged on the mounting part and in one-to-one correspondence with the plurality of connecting terminals, each magnetic conductor having a first coupling space and a second coupling space, the connecting terminal passing through a corresponding first coupling space, the first connecting end and the second connecting end respectively extending out of the mounting part, and the plurality of second coupling spaces being arranged in correspondence with the plurality of induction elements and located on an outer side of the mounting part; wherein the power assembly is electrically connected to the drive motor through the terminal block, the induction elements extend into corresponding second coupling spaces, and meanwhile, an induced magnetic field generated by the connecting terminal acts on the induction element through the magnetic conductor.

In the terminal connector and the electric drive assembly of the embodiments of the present disclosure, the terminal block and the magnetic conductors are arranged on the mounting part. The terminal block has a plurality of connecting terminals for transmitting three-phase electricity, and the first connecting ends and the second connecting ends of the connecting terminals extend out of the mounting part, so as to be electrically connected to the motor controller and the drive motor respectively. Therefore, the connecting terminals pass through the first coupling spaces of the magnetic conductors, so that the induced magnetic field generated by the connecting terminals is coupled to the magnetic conductors. At the same time, the second coupling spaces are arranged on the outer side of the mounting part.

### BRIEF DESCRIPTION OF THE DRAWINGS

Through the following description of the embodiments of the present disclosure with reference to the drawings, the above and other objectives, features and advantages of the present disclosure will be more apparent. In the drawings:

FIG. 1 is a structural schematic diagram of one side of the terminal connector according to the embodiment of the present disclosure;

FIG. 2 is a structural schematic diagram of another side of the terminal connector according to the embodiment of the present disclosure;

FIG. 3 is a cross-sectional schematic diagram of the terminal connector according to the embodiment of the present disclosure;

FIG. 4 is an exploded schematic diagram of one side of the terminal connector according to the embodiment of the present disclosure;

FIG. 5 is an exploded schematic diagram of another side of the terminal connector according to the embodiment of the present disclosure;

FIG. 6 is a partial schematic diagram of one side of the terminal connector according to the embodiment of the present disclosure;

FIG. 7 is a partial schematic diagram of another side of the terminal connector according to the embodiment of the present disclosure;

FIG. 8 is a schematic diagram of the positional relationship among the magnetic conductor, the first extending section and the induction element according to the embodiment of the present disclosure;

FIG. 9 is a cross-sectional schematic diagram of the terminal connector in some implementation manners according to the embodiment of the present disclosure;

FIG. 10 is a cross-sectional schematic diagram of the terminal connector in other implementation manners according to the embodiment of the present disclosure;

FIG. 11 is a schematic diagram of the positional relationship between the convex block and the circuit board according to the embodiment of the present disclosure;

FIG. 12 is a circuit schematic diagram of the electric drive assembly according to the embodiment of the present disclosure.

### DETAILED DESCRIPTION OF EMBODIMENTS OF THE DISCLOSURE

The present disclosure will be described below based on the embodiments, but the present disclosure is not limited only to these embodiments. In the following detailed description of the present disclosure, some specific details are described in detail. Those skilled in the art may fully understand the present disclosure without the description of these detailed details. In order to avoid obscuring the essence of the present disclosure, the well-known methods, processes, procedures, components and circuits are not described in detail.

In addition, those of ordinary skill in the art should understand that the drawings provided herein are for illustrative purposes and are not necessarily drawn to scale.

Unless the context clearly requires, the words “include”, “comprise” and the like in the entire application document should be interpreted as inclusive rather than exclusive or exhaustive; that is, they mean “including but not limited to”.

In the description of the present disclosure, it should be understood that the terms “first” and “second” are only used for descriptive purposes and cannot be understood as indicating or implying relative importance. In addition, in the description of the present disclosure, unless otherwise specified, “plurality”means two or more.

Unless otherwise clearly specified and limited, the terms “mount”, “connect”, “fix” and the like should be understood in a broad sense. For example, they may be fixed connections, detachable connections or integral connections; they may be direct connections or indirect connections through an intermediate medium; they may be the internal communication of two elements or the interaction relationship between two elements. For those of ordinary skill in the art, the specific meanings of the above terms in the present disclosure may be understood according to specific situations.

For the convenience of description, spatially relative terms such as “inside”, “outside”, “below”, “lower part”, “above” and “upper part” are used herein to describe the relationship between one element or feature and another element or feature shown in the drawings. It will be understood that the spatially relative terms are intended to include different orientations of the device in use or operation other than the orientation depicted in the drawings. For example, if the device in the drawing is turned over, elements described as “below” or “under” other elements or features will then be oriented “above” the other elements or features. Thus, the example term “below” may include both upper and lower orientations. The device may be oriented in other ways rotated by 90 degrees or in other orientations, and the spatially relative descriptors used herein should be interpreted accordingly.

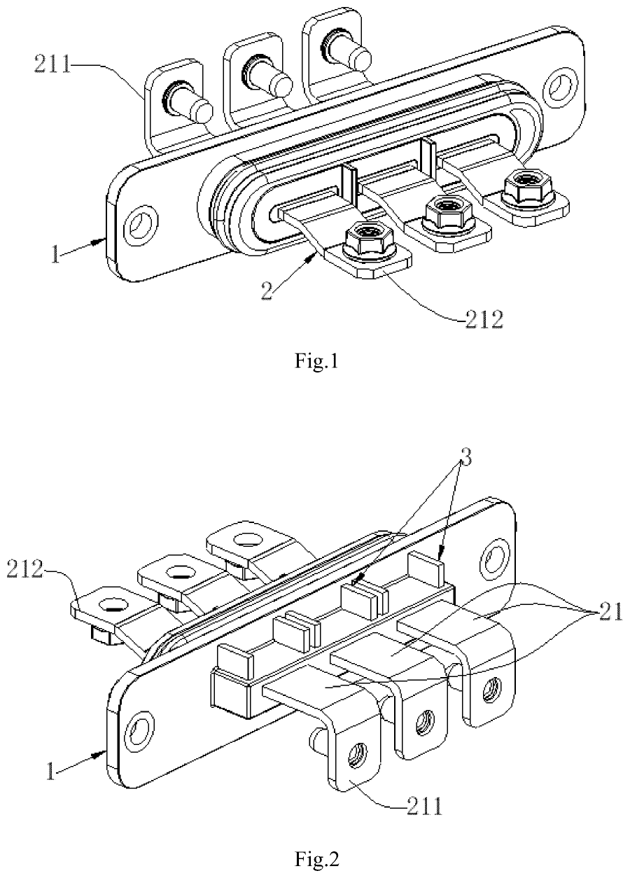

FIGS. 1 and 2 are structural schematic diagrams of the terminal connector of the present embodiment.

In some implementation manners, as shown in FIGS. 1 and 2, the terminal connector in the present embodiment includes a mounting part 1, a terminal block 2 and a plurality of magnetic conductors 3. The terminal block 2 and the magnetic conductors 3 are fixed on the mounting part 1 together. The terminal block 2 includes a plurality of connecting terminals 21 in one-to-one correspondence with the plurality of magnetic conductors 3. The connecting terminal 21 includes a first connecting end 211 and a second connecting end 212, and the first connecting end 211 and the second connecting end 212 extend out of the mounting part 1.

The first connecting end 211 is used for electrical connection with the motor controller 9. The second connecting end 212 is used for electrical connection with the drive motor 8. Thus, the drive control of the drive motor 8 by the motor controller 9 is realized. The connecting terminal 21 may be made of materials such as copper, iron, aluminum or alloy.

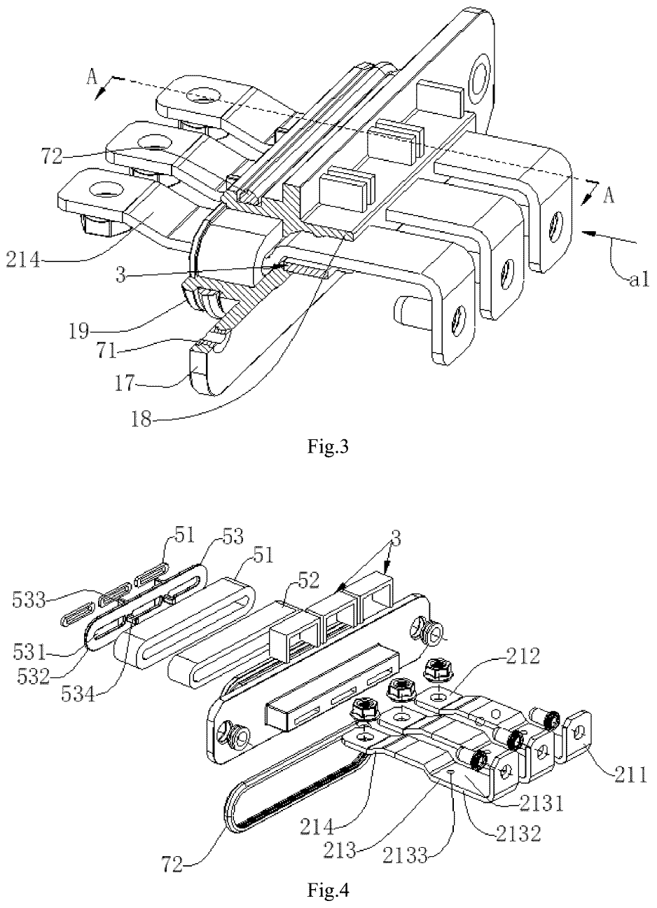

FIG. 3 is a cross-sectional schematic diagram of the terminal connector of the present embodiment. The mounting part 1 may be configured as an injection-molded part, and its material may be plastic or rubber, etc.

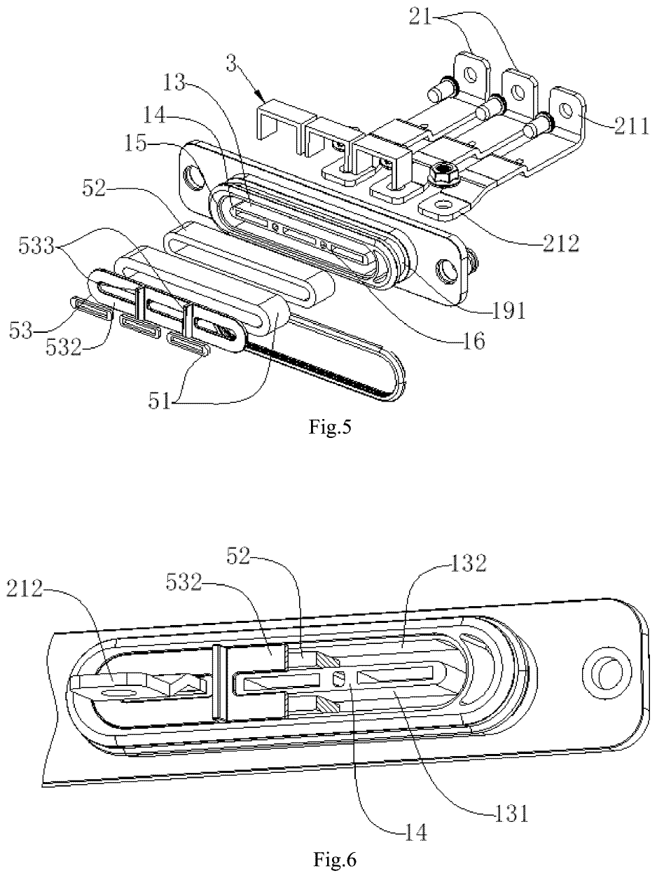

FIGS. 4 and 5 are exploded schematic diagrams of the terminal connector of the present embodiment. The terminal connector in the figures includes three connecting terminals 21, and the three connecting terminals 21 are arranged at intervals. The magnetic conductors 3 and part of the terminal block 2 are arranged on an inner side of the mounting part 1 at intervals, so that the structure of the terminal connector is more compact, and the electrical gap between the plurality of connecting terminals 21 is maintained.

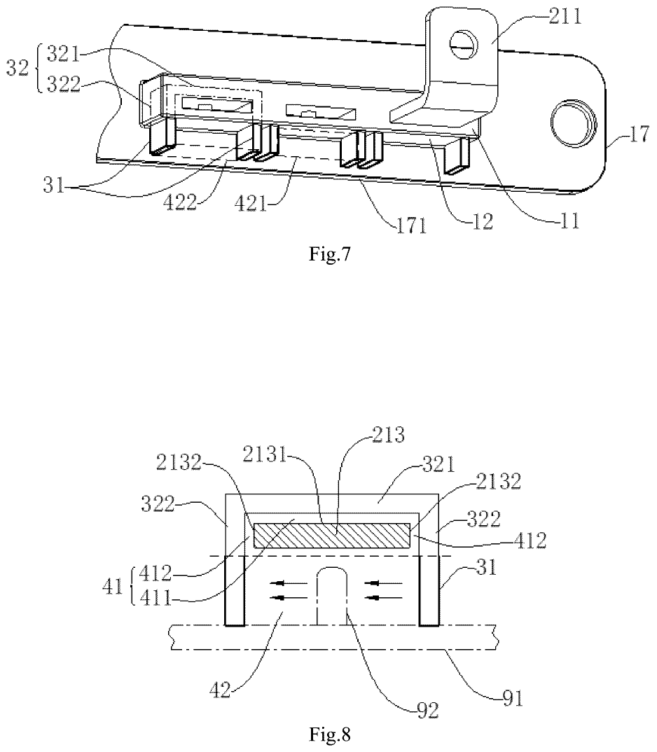

FIGS. 6 and 7 are partial schematic diagrams of the terminal connector of the present embodiment. The second connecting end 212 in FIG. 6 extends horizontally. The head of the first connecting end 211 in FIG. 7 is bent upward, and the outline of one magnetic conductor 3 arranged on the inner side of the mounting part 1 is shown by a dot-dash line.

FIG. 8 is a schematic diagram of the positional relationship among the magnetic conductor 3, the first extending section 213 and the induction element 92 of the present embodiment. The outlines of the circuit board 91 of the motor controller 9 and the induction element 92 arranged on the circuit board 91 in the figure are shown by dot-dash lines. The spaces above and below the dotted line are the first coupling space 41 and the second coupling space 42 respectively. The arrows in the figure are schematic diagrams of the flow direction of the electromagnetic field in the second coupling space 42.

In some implementation manners, as shown in FIGS. 7 and 8, the magnetic conductor 3 has a first coupling space 41 and a second coupling space 42, and the connecting terminal 21 passes through the corresponding first coupling space 41. When alternating current is transmitted on the connecting terminal 21, the alternating current will generate an induced magnetic field near the connecting terminal 21, and the induced magnetic field may be coupled to the magnetic conductor 3 through the first coupling space 41. At the same time, the plurality of second coupling spaces 42 are arranged at intervals and located on the outer side of the mounting part 1, so that after the terminal connector is mounted on the motor controller 9, the induction elements 92 may directly extend into the inner side of the second coupling spaces 42, thereby indirectly detecting the current in the connecting terminals 21. That is, the induced magnetic field generated by the connecting terminal 21 acts on the second coupling space 42 through the first coupling space 41, and acts on the induction element 92 through the second coupling space 42.

Specifically, the induction element 92 in the present embodiment may be a Hall element. The Hall element is arranged in the second coupling space 42 and does not directly contact the magnetic conductor 3. As shown by the arrow in FIG. 8, the magnetic field generated by the second coupling space 42 will pass through the Hall element. The Hall element, together with the circuit board 91, the magnetic conductor 3 and the region of the connecting terminal 21 located in the first coupling space 41, forms a Hall current sensor. The current sensor is a non-contact current sensor.

To sum up, in the terminal connector of the present embodiment, the terminal block 2 and the magnetic conductors 3 are arranged on the mounting part 1. The terminal block 2 has a plurality of connecting terminals 21 for transmitting three-phase electricity, and the first connecting ends 211 and the second connecting ends 212 of the connecting terminals 21 extend out of the mounting part 1, so as to be electrically connected to the motor controller 9 and the drive motor 8 respectively. Therefore, the connecting terminals 21 pass through the first coupling spaces 41 of the magnetic conductors 3, so that the induced magnetic field generated by the connecting terminals 21 may be coupled to the magnetic conductors 3. At the same time, the second coupling spaces 42 are arranged on the outer side of the mounting part 1, so that when the terminal connector is connected to the motor controller 9, the induction elements 92 may be arranged on the inner side of the second coupling spaces 42. Thus, the monitoring of the current on the connecting terminals 21 is realized. On the other hand, the arrangement space for directly arranging current sensors on the circuit board 91 is also saved. Meanwhile, the terminal block 2 may be directly electrically connected to the power assembly 93, so that it is avoided to arrange current sensors between the terminal block 2 and the power assembly 93, and the length of the conductive path is shortened.

In some implementation manners, as shown in FIGS. 7 and 8, the magnetic conductor 3 includes two extending ends 31 and a bending section 32 in the extending direction. The bending section 32 is located between the two extending ends 31 and bends to form the first coupling space 41. The two extending ends 31 extend out of the mounting part 1, and the two extending ends 31 are arranged at intervals, and the opposite sides thereof form the second coupling space 42. The magnetic conductor 3 in the present embodiment is fixed on the mounting part 1 through the bending section 32.

Specifically, the magnetic conductor 3 is made of silicon steel. The induction element 92 is arranged in the middle position of the two extending ends 31, that is, the distance from the induction element 92 to the two extending ends 31 is the same. At the same time, the bending section 32 surrounds the upper area and two side areas of the connecting terminal 21, so as to increase the coupling strength between the connecting terminal 21 and the magnetic conductor 3. Meanwhile, the two extending ends 31 may be equivalent to two pole plates. The magnetic field between the two pole plates may pass through the induction element 92. Those skilled in the art may adjust the coupling strength between the magnetic conductor 3 and the induction element 92 by changing the distance between the two pole plates.

In some implementation manners, as shown in FIGS. 7 and 8, the bending section 32 includes a first segment 321 and two second segments 322 in the extending direction, and the two second segments 322 are connected to the two ends of the first segment 321 and perpendicular to the first segment 321. Specifically, one first segment 321 extends along the same straight line as one extending end 31, and the other second segment 322 extends along the same straight line as the other extending end 31.

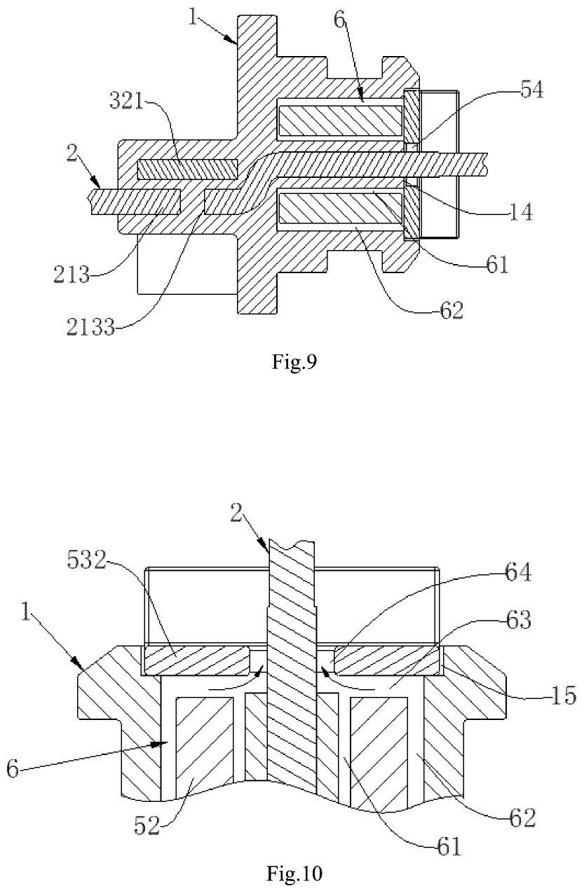

FIG. 9 is a cross-sectional schematic diagram of the terminal connector in some implementation manners of the present embodiment. The cross-sectional position in the figure is as shown at A-A in FIG. 3, and the filler glue 51 is not shown in the figure.

With further reference to FIGS. 4 and 9, the connecting terminal 21 includes a first extending section 213 in the extending direction. The first extending section 213 is located between the first connecting end 211 and the second connecting end 212. The first extending section 213 has a first side surface 2131 and two second side surfaces 2132. The first side surface 2131 faces the first segment 321 and forms a first coupling gap 411. The two second side surfaces 2132 face the two second segments 322 respectively and form two second coupling gaps 412.

The shape of the bending section 32 in the present embodiment matches the cross-sectional shape of the first extending section 213. The mounting part 1 is filled in the region between the bending section 32 and the first extending section 213 to ensure the coupling strength between them and avoid direct contact between the connecting terminal 21 and the magnetic conductor 3.

In some implementation manners, as shown in FIG. 7, the mounting part 1 has a first mounting surface 11 and a second mounting surface 12 facing the side of the first mounting surface 11, and the first connecting end 211 extends out of the first mounting surface 11. The two extending ends 31 of the same magnetic conductor 3 extend out of the second mounting surface 12 and form an accommodating groove with the first mounting surface 11.

Specifically, the first mounting surface 11 and the second mounting surface 12 in the present embodiment are perpendicular to each other and adjacently arranged. When the first connecting end 211 is electrically connected to the power assembly 93, the second mounting surface 12 faces the edge of the circuit board 91, so that the induction element 92 arranged on the circuit board 91 may just extend into the accommodating groove, and then be coupled with the magnetic conductor 3.

Optionally, when the terminal connector is in a connected state with the motor controller 9, the two extending ends 31 are in contact with the circuit board 91, so that the accommodating groove is buckled on the induction element 92.

In some implementation manners, as shown in FIGS. 7 and 8, the mounting part 1 is an injection-molded part. The bending section 32 and part of the connecting terminals 21 are arranged on the inner side of the mounting part 1 at intervals. The magnetic conductor 3 and the terminal block 2 in the present embodiment are fixed in the mounting part 1 as inserts to form a connecting component. The connecting component is made by insert molding process, so that it has certain electrical performance, and the connection mode between the terminal connector and the motor controller 9 may be simplified.

In some implementation manners, as shown in FIGS. 4, 7 and 9, the connecting terminal 21 includes a first extending section 213 in the extending direction. The first extending section 213 is located between the first connecting end 211 and the second connecting end 212, and the first extending section 213 is fixed in the mounting part 1 as an insert. The first extending section 213 is provided with a connecting through-hole 2133 corresponding to the bending section 32, that is, the connecting through-hole 2133 is located on the inner side of the first coupling space 41 and arranged facing the first segment 321. The injection-molded part fills the connecting through-hole 2133.

In the present embodiment, when the terminal connector is connected between the motor assembly and the motor controller 9, the stress between them will act on the terminal block 2. By arranging the connecting through-hole 2133 in the injection-molded part, the connection strength between the connecting terminal 21 and the mounting part 1 may be increased, and the terminal block 2 is prevented from loosening on the mounting part 1. On the other hand, in order to ensure the coupling strength between the first coupling space 41 and the first extending section 213, the bending section 32 is relatively close to the first extending section 213, which reduces the strength of the mounting part 1 in this region. For this reason, the connecting through-hole 2133 is arranged in the first extending section 213 to increase the structural strength of the mounting part 1 in this region.

In some implementation manners, as shown in FIGS. 4 to 6, the terminal connector further includes filler glue 51 and a magnetic ring 52. The magnetic ring 52 surrounds the terminal block 2 and is arranged at intervals from the terminal block 2. The magnetic ring 52 in the present embodiment is used for filtering the common-mode noise interference of the terminal block 2 and reducing the damage to the drive motor 8 caused by the noise.

The mounting part 1 has a mounting ring groove 13, the plurality of second connecting ends 212 extend out from the center of the mounting ring groove 13, the magnetic ring 52 is arranged in the mounting ring groove 13 and forms at least a part of a filling gap 6 with the inner wall of the mounting ring groove 13, and the filler glue 51 fills the filling gap 6. Specifically, the magnetic ring 52 is made of nanocrystalline material.

It is easy to understand that after the filler glue 51 in the present embodiment is cured, the filler glue 51 is located between the magnetic ring 52 and the inner wall of the mounting ring groove 13. When the electric vehicle is running, the vibration generated by the vehicle will be transmitted to the nanocrystalline magnetic ring 52, causing damage to the nanocrystalline magnetic ring 52. For this reason, by arranging the filler glue 51 between the mounting ring groove 13 and the nanocrystalline magnetic ring 52, the fixing process of the magnetic ring 52 may be simplified, and the filler glue 51 may absorb vibration to reduce the impact on the magnetic ring 52.

In some implementation manners, as shown in FIG. 6, the mounting ring groove 13 has a first inner side surface 131 and a second inner side surface 132 facing opposite directions. The first inner side surface 131 is closer to the central region of the mounting ring groove 13 than the second inner side surface 132.

With further reference to FIG. 9, the magnetic ring 52 is arranged between the first inner side surface 131 and the second inner side surface 132 at intervals, and forms a first filling gap 61 and a second filling gap 62 with the first inner side surface 131 and the second inner side surface 132 respectively. Thus, the filler glue 51 may fix the magnetic ring 52 at the inner side and the outer side of the magnetic ring 52 at the same time, so that the stress on the magnetic ring 52 in all directions is more balanced.

In some implementation manners, as shown in FIGS. 4 and 5, the terminal connector further includes a cover part 53. The cover part 53 covers the mounting ring groove 13 and is provided with a plurality of windows 531, and the plurality of second connecting ends 212 respectively extend out from the plurality of windows 531 in one-to-one correspondence. The cover part 53 in the present embodiment may further fix the magnetic ring 52 in the axial direction of the magnetic ring 52, making the magnetic ring 52 more stable. In this form, the cover part 53 may be fixed on the mounting part 1 through the filler glue 51.

In an optional implementation manner, the terminal connector in the present embodiment may be assembled in the following way. Firstly, filling the filler glue 51 into the bottom of the mounting ring groove 13, and the filling amount may be controlled to be about a quarter of the volume of the mounting ring groove 13. Secondly, pressing the magnetic ring 52 into the mounting ring groove 13 until the magnetic ring 52 abuts against the bottom of the mounting ring groove 13, or until the magnetic ring 52 completely enters the mounting ring groove 13 (the magnetic ring 52 keeps a gap with the bottom of the mounting ring groove 13). During this process, the magnetic ring 52 will squeeze the filler glue 51, making the filler glue 51 flow to the positions of the first filling gap 61 and the second filling gap 62. Thirdly, the operator applies the filler glue 51 to the end surface of the magnetic ring 52 far away from the bottom of the mounting ring groove 13, and then covers the cover part 53 on the mounting ring groove 13 to fix the cover part 53 through the filler glue 51. Finally, the operator wipes off the filler glue 51 flowing out of the outer side of the cover part 53, and after the filler glue 51 is cured, the installation of the magnetic ring 52 may be completed.

In some implementation manners, as shown in FIGS. 6 and 9, the mounting part 1 has a positioning surface 14, and the mounting ring groove 13 is arranged around the positioning surface 14. The window edge of the window 531 abuts against the positioning surface 14, the window 531 is arranged at intervals from the corresponding connecting terminal 21, a filling groove 54 is formed between the window 531 and the positioning surface 14 as well as the connecting terminal 21, and the filler glue 51 fills the filling groove 54.

In the present embodiment, after the cover part 53 is covered on the mounting ring groove 13, the operator fills the filler glue 51 into the filling groove 54 again, so as to further fix the cover part 53. At the same time, the filler glue 51 may also seal the side of the terminal connector close to the motor assembly, so as to prevent the oil and gas on the drive motor 8 from flowing to the side of the terminal connector close to the motor controller 9 along the terminal block 2.

FIG. 10 is a cross-sectional schematic diagram of the terminal connector in other implementation manners of the present embodiment.

In some implementation manners, as shown in FIGS. 5 and 6, the mounting part 1 has a positioning groove 15, and the positioning groove 15 is arranged around the mounting ring groove 13. With further reference to FIG. 10, the cover part 53 includes a baffle plate 532, the magnetic ring 52 is arranged at intervals from the baffle plate 532, a third filling gap 63 is formed between the end surface of the magnetic ring 52 and the baffle plate 532, and a fourth filling gap 64 is formed between the window 531 and the corresponding connecting terminal 21.

When the edge of the baffle plate 532 is lapped on the positioning groove 15, the fourth filling gap 64 is communicated with the mounting ring groove 13 through the third filling gap 63, and the filler glue 51 fills the third filling gap 63 and the fourth filling gap 64.

In an optional implementation manner, the terminal connector in the present embodiment may be assembled in the following way. Firstly, filling the filler glue 51 into the bottom of the mounting ring groove 13, and the filling amount may be controlled to be about one-third of the volume of the mounting ring groove 13. Secondly, pressing the magnetic ring 52 into the mounting ring groove 13 until the magnetic ring 52 abuts against the bottom of the mounting ring groove 13, or until the magnetic ring 52 completely enters the mounting ring groove 13 (the magnetic ring 52 keeps a gap with the bottom of the mounting ring groove 13). During this process, the magnetic ring 52 will squeeze the filler glue 51, making the filler glue 51 flow to the first filling gap 61 and the second filling gap 62, and flow from the first filling gap 61 and the second filling gap 62 to the positioning groove 15. That is, the magnetic ring 52 is completely immersed in the filler glue 51. Thirdly, the operator directly covers the baffle plate 532 on the positioning groove 15. At this time, the filler glue 51 is squeezed, forcing it to further flow from the third filling gap 63 into the fourth filling gap 64 (as shown by the arrow in FIG. 10, the baffle plate 532 is arranged at intervals from the center position of the mounting ring groove 13). Finally, the operator wipes off the filler glue 51 flowing out of the outer side of the cover part 53, and after the filler glue 51 is cured, the installation of the magnetic ring 52 may be completed. Thus, the process of filling the filler glue 51 once may be omitted.

In some implementation manners, as shown in FIGS. 4 and 5, the cover part 53 further includes a plurality of isolation strips 533, the isolation strips 533 are convexly arranged on the plate surface of the baffle plate 532 far away from the mounting ring groove 13, the isolation strips 533 are located between two windows 531, and the extending direction of the isolation strips 533 is perpendicular to the arrangement direction of the plurality of windows 531. Specifically, the connecting terminal 21 corresponds to the central region of the isolation strip 533.

The isolation strip 533 in the present embodiment is used for increasing the creepage distance between two adjacent connecting terminals 21 on the cover part 53. The creepage distance refers to the charged area where the insulation material around the conductor is polarized along the measured surface between two conductive parts, resulting in the electrified phenomenon of the insulation material. Thus, the mutual interference of currents on two adjacent connecting terminals 21 may be avoided.

In some implementation manners, as shown in FIG. 5, the mounting part 1 has a plurality of slots 16. With further reference to FIG. 4, the cover part 53 includes a plurality of positioning columns 534, and the plurality of positioning columns 534 are convexly arranged on the side of the cover part 53 facing the mounting ring groove 13. When the cover part 53 covers the mounting ring groove 13, the plurality of positioning columns 534 are inserted into the plurality of slots 16 in one-to-one correspondence. Thus, the accurate positioning of the cover part 53 and the mounting part 1 is realized.

Further, the end of the positioning column 534 is arranged at intervals from the bottom of the slot 16. Thus, it is ensured that the baffle plate 532 may be attached to the bottom surface of the positioning groove 15. Before the filler glue 51 is cured, the cover part 53 is prevented from moving on the mounting part 1.

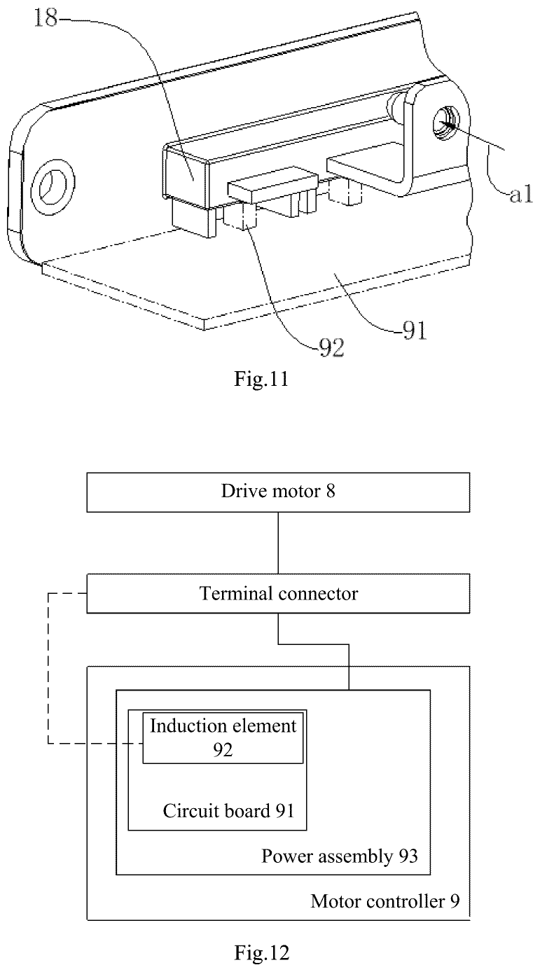

FIG. 11 is a schematic diagram of the positional relationship between the convex block 18 and the circuit board 91 of the present embodiment. The induction element 92 and the circuit board 91 in the figure are shown by dot-dash lines.

In some implementation manners, as shown in FIGS. 3 and 11, the mounting part 1 includes a connecting plate 17 and a convex block 18. With further reference to FIG. 7, the connecting plate 17 has a first plate edge 171, and the first plate edge 171 extends along the length direction of the connecting plate 17. The convex block 18 is convexly arranged on one plate surface of the connecting plate 17, the magnetic conductors 3 are arranged on the convex block 18 and arranged at intervals along the extending direction of the first plate edge 171, and the plurality of extending ends 31 are located between the convex block 18 and the first plate edge 171.

Specifically, the convex block 18 in the present embodiment is used for fixing the bending section 32. The induction element 92 is arranged at the edge position of the circuit board 91. After the terminal connector is connected to the motor controller 9, the edge of the circuit board 91 is just adjacent to the first plate edge 171 and is located below the convex block 18. At this time, the accommodating groove may cover the induction element 92, so that the bending section 32 is just located above the induction element 92.

In some implementation manners, as shown in FIG. 3, the terminal connector further includes two connecting bushings 71. The two connecting bushings 71 are fixed in the connecting plate 17 as inserts and located on both sides of the convex block 18. The connecting bushing 71 may be made of alloy material, and the connecting bushing 71 has a through-hole. When a screw passes through the through-hole to connect with the motor assembly or the motor controller 9, the two connecting bushings 71 may effectively improve the connection strength and make the connection more stable.

In some implementation manners, as shown in FIG. 3, the terminal connector further includes a sealing ring 72. The mounting part 1 further includes a plug-in body 19. The plug-in body 19 is convexly arranged on the plate surface of the connecting plate 17 far away from the convex block 18 and has a sealing groove 191, the second connecting end 212 extends out from the plug-in body 19, and the sealing ring 72 is sleeved in the sealing groove 191. The cooperation between the sealing ring 72 and the sealing groove 191 in the present embodiment may increase the sealing effect between the terminal connector and the motor assembly, and prevent substances such as oil and gas from leaking to the outside through the connection position.

In some implementation manners, as shown in FIGS. 3 and 4, the connecting terminal 21 includes a second extending section 214 in the extending direction, the second extending section 214 is located between the second connecting end 212 and the mounting part 1, and the second extending section 214 is made of soft copper material. The second extending section 214 in the present embodiment has a certain deformation capacity. When the connecting terminal 21 is fixedly connected between the motor assembly and the drive motor 8, the soft copper material helps the second connecting end 212 to connect with the connecting contact of the motor assembly. At the same time, the stress generated on the connecting terminal 21 due to the vibration of the motor assembly itself is reduced.

Optionally, the second extending section 214 in the present embodiment may be connected between the first extending section 213 and the second connecting end 212 by welding, and the first extending section 213, the second connecting end 212 and the first connecting end 211 are all made of hard copper material. Thus, it is ensured that the connecting terminal 21 still has a certain rigidity.

Further, the connecting terminal 21 is of a strip-shaped structure, and the second extending section 214 has a first extending state and a second extending state. When the second extending section 214 is in the first extending state as shown in FIG. 4, the plurality of second extending sections 214 are bent along the thickness direction of the strip-shaped structure. So that the second connecting end 212 is closer to the connecting contact on the motor assembly. When the second extending section 214 is in the second extending state, the bending amplitude of the second extending section 214 is smaller than that in the first extending state (for example, the second extending section 214 extends along a straight line), and the second extending section 214 is suitable for passing through the magnetic ring 52.

The operator may first flatten the second extending section 214 so that the connecting terminal 21 may pass through the magnetic ring 52. After the magnetic ring 52 enters the mounting ring groove 13, the operator may bend the second extending section 214 again. Thus, it is convenient to pass the magnetic ring 52 through the second connecting end 212 and arrange it in the mounting ring groove 13.

FIG. 12 is a circuit schematic diagram of the electric drive assembly of the present embodiment.

In an optional implementation manner, as shown in FIG. 12, the terminal connector in the above embodiment may be applied to an electric drive assembly. The electric drive assembly includes a drive motor 8, a motor controller 9 and a terminal connector. The motor controller 9 includes a power assembly 93, and the power assembly 93 includes a circuit board 91 and a plurality of induction elements 92 arranged on the circuit board 91. The power assembly 93 is electrically connected to the drive motor 8 through the terminal connector to drive the drive motor 8 to rotate.

With further reference to FIGS. 1 to 8, the terminal connector includes a mounting part 1, a terminal block 2 and a plurality of magnetic conductors 3. The terminal block 2 is arranged on the mounting part 1 and includes a plurality of connecting terminals 21, each connecting terminal 21 includes a first connecting end 211 and a second connecting end 212, and the plurality of magnetic conductors 3 are arranged on the mounting part 1 and in one-to-one correspondence with the plurality of connecting terminals 21. Specifically, the terminal block 2 includes three connecting terminals 21, and the three connecting terminals 21 are respectively used for connecting with the terminal U, terminal V and terminal W of the winding of the drive motor 8.

The magnetic conductor 3 has a first coupling space 41 and a second coupling space 42, the connecting terminal 21 passes through the corresponding first coupling space 41, the first connecting end 211 and the second connecting end 212 respectively extend out of the mounting part 1, and the plurality of second coupling spaces 42 are arranged in correspondence with the plurality of induction elements 92 and located on the outer side of the mounting part 1. The power assembly 93 is electrically connected to the drive motor 8 through the terminal block 2, the induction elements 92 extend into the corresponding second coupling spaces 42, and meanwhile, the induced magnetic field generated by the connecting terminals 21 acts on the induction elements 92 through the magnetic conductors 3.

To sum up, in the electric drive assembly of the present embodiment, the terminal block 2 and the magnetic conductor 3 of the terminal connector are arranged on the mounting part 1. The terminal block 2 has a plurality of connecting terminals 21 for transmitting three-phase electricity, and the first connecting ends 211 and the second connecting ends 212 of the connecting terminals 21 extend out of the mounting part 1, so as to be electrically connected to the motor controller 9 and the drive motor 8 respectively. Therefore, the connecting terminal 21 passes through the first coupling space 41 of the magnetic conductor 3, so that the induced magnetic field generated by the connecting terminal 21 is coupled to the magnetic conductor 3. At the same time, the second coupling space 42 is arranged on the outer side of the mounting part 1, so that when the terminal connector is connected to the motor controller 9, the induction element 92 may be arranged on the inner side of the second coupling space 42. Thus, the monitoring of the current on the connecting terminal 21 is realized. On the other hand, the arrangement space for directly arranging current sensors on the circuit board 91 is also saved. Meanwhile, the terminal block 2 may be directly electrically connected to the power assembly 93, so that it is avoided to arrange current sensors between the terminal block 2 and the power assembly 93, and the length of the conductive path is shortened.

In some implementation manners, as shown in FIG. 7, the sides of the two extending ends 31 close to the first mounting surface 11 are provided with a first side opening 421, and the first side opening 421 is located on the side of the magnetic conductor 3 far away from the connecting plate 17. The sides of the two extending ends 31 far away from the second mounting surface 12 are provided with a second side opening 422. During the process of fixing and connecting the mounting part 1 with the motor controller 9, the induction element 92 enters the accommodating groove through the first side opening 421 or the second side opening 422. Thus, the induction element 92 is prevented from interfering with the magnetic conductor 3 during the installation process.

Specifically, the first connecting end 211 is arranged in a bent manner, and the first connecting end 211 is provided with a connecting hole. The axial direction of the connecting hole is consistent with the direction of the first side opening 421. A nut may also be arranged on the first connecting end 211. When the connecting head on the motor controller 9 is connected with the nut along the axial direction of the connecting hole (as shown by the arrow a1 in FIGS. 3 and 11), the induction element 92 may enter the accommodating groove from the first side opening 421. Thus, the connection process between the terminal connector and the motor controller 9 is simplified.

The above are only the preferred embodiments of the present disclosure and are not intended to limit the present disclosure. For those skilled in the art, the present disclosure may have various modifications and changes. Any modification, equivalent replacement, improvement, etc. made within the spirit and principle of the present disclosure shall be included in the protection scope of the present disclosure.

I/We claim:

1. A terminal connector, comprising:
a mounting part;
a terminal block arranged on the mounting part and including a plurality of connecting terminals, wherein each connecting terminal includes a first connecting end and a second connecting end; and
a plurality of magnetic conductors arranged on the mounting part at intervals and in one-to-one correspondence with the plurality of connecting terminals, wherein each magnetic conductor has a first coupling space and a second coupling space, the connecting terminal passes through a corresponding first coupling space, the first connecting end and the second connecting end respectively extend out of the mounting part, and a plurality of second coupling spaces are arranged at intervals and located on an outer side of the mounting part;
wherein an induced magnetic field generated by the connecting terminal acts on the second coupling space through the first coupling space.

2. The terminal connector according to claim 1, wherein the magnetic conductor includes two extending ends and a bending section in an extending direction, and the bending section is located between the two extending ends and bends to form the first coupling space;
the two extending ends extend out of the mounting part, and the two extending ends are arranged at intervals, and opposite sides of the two extending ends form the second coupling space.

3. The terminal connector according to claim 2, wherein the bending section includes a first segment and two second segments in the extending direction, and the two second segments are connected to two ends of the first segment and perpendicular to the first segment;
the connecting terminal includes a first extending section in the extending direction, the first extending section is located between the first connecting end and the second connecting end, the first extending section has a first side surface and two second side surfaces, the first side surface faces the first segment and forms a first coupling gap, and the two second side surfaces face the two second segments respectively and form two second coupling gaps.

4. The terminal connector according to claim 2, wherein the mounting part has a first mounting surface and a second mounting surface facing the side of the first mounting surface, and the first connecting end extends out of the first mounting surface;
the two extending ends of a same magnetic conductor extend out of the second mounting surface and form an accommodating groove with the first mounting surface.

5. The terminal connector according to claim 2, wherein the mounting part is an injection-molded part, and the bending section and part of the connecting terminals are arranged on an inner side of the mounting part at intervals.

6. The terminal connector according to claim 5, wherein the connecting terminal includes a first extending section in the extending direction, the first extending section is located between the first connecting end and the second connecting end and is fixed in the mounting part as an insert, the first extending section is provided with a connecting through-hole corresponding to the bending section, and the injection-molded part fills the connecting through-hole.

7. The terminal connector according to claim 1, further comprising:
filler glue; and
a magnetic ring surrounding the terminal block and spaced apart from the terminal block;
wherein the mounting part has a mounting ring groove, a plurality of second connecting ends extend out from a center of the mounting ring groove, the magnetic ring is arranged in the mounting ring groove and forms at least a part of a filling gap with an inner wall of the mounting ring groove, and the filler glue fills the filling gap.

8. The terminal connector according to claim 7, wherein the mounting ring groove has a first inner side surface and a second inner side surface facing opposite directions;
the magnetic ring is arranged between the first inner side surface and the second inner side surface at intervals, and forms a first filling gap and a second filling gap with the first inner side surface and the second inner side surface respectively.

9. The terminal connector according to claim 7, further comprising:
a cover part covering the mounting ring groove and provided with a plurality of windows, and the plurality of second connecting ends respectively extend out from the plurality of windows in one-to-one correspondence.

10. The terminal connector according to claim 9, wherein the mounting part has a positioning surface, and the mounting ring groove is arranged around the positioning surface;
a window edge of a window abuts against the positioning surface, the window is arranged at intervals from a corresponding connecting terminal, a filling groove is formed between the window and the positioning surface as well as the connecting terminal, and the filler glue fills the filling groove.

11. The terminal connector according to claim 9, wherein the mounting part has a positioning groove, and the positioning groove is arranged around the mounting ring groove;
the cover part includes a baffle plate, the magnetic ring is arranged at intervals from the baffle plate, a third filling gap is formed between an end surface of the magnetic ring and the baffle plate, and a fourth filling gap is formed between a window and a corresponding connecting terminal;
an edge of the baffle plate is lapped on the positioning groove, the fourth filling gap is communicated with the mounting ring groove through the third filling gap, and the filler glue fills the third filling gap and the fourth filling gap.

12. The terminal connector according to claim 7, wherein the magnetic ring is made of nanocrystalline material, and the magnetic conductor is made of silicon steel.

13. The terminal connector according to claim 11, wherein the cover part further includes a plurality of isolation strips, the isolation strips are convexly arranged on a plate surface of the baffle plate far away from the mounting ring groove, the isolation strips are located between two windows, and an extending direction of the isolation strips is perpendicular to an arrangement direction of the plurality of windows.

14. The terminal connector according to claim 9, wherein the mounting part has a plurality of slots;
the cover part includes a plurality of positioning columns, and the plurality of positioning columns are convexly arranged on a side of the cover part facing the mounting ring groove;
the cover part covers the mounting ring groove, and the plurality of positioning columns are inserted into the plurality of slots in one-to-one correspondence.

15. The terminal connector according to claim 5, wherein the mounting part includes a connecting plate and a convex block, the connecting plate has a first plate edge, and the first plate edge extends along a length direction of the connecting plate;
the convex block is convexly arranged on a plate surface of the connecting plate, the magnetic conductors are arranged on the convex block and arranged at intervals along an extending direction of the first plate edge, and a plurality of extending ends 31 are located between the convex block and the first plate edge.

16. The terminal connector according to claim 15, further comprising:
two connecting bushings fixed in the connecting plate as inserts and located on two sides of the convex block.

17. The terminal connector according to claim 15, wherein the terminal connector further comprises a sealing ring;
the mounting part further comprises:
a plug-in body convexly arranged on a plate surface of the connecting plate far away from the convex block and having a sealing groove, the second connecting end extending out from the plug-in body, and the sealing ring being sleeved in the sealing groove.

18. The terminal connector according to claim 7, wherein the connecting terminal includes a second extending section in an extending direction, the second extending section is located between the second connecting end and the mounting part, and the second extending section is made of soft copper material.

19. The terminal connector according to claim 18, wherein the connecting terminal is of a strip-shaped structure, and the second extending section has a first extending state and a second extending state;
in the first extending state, the plurality of second extending sections are bent along a thickness direction of the strip-shaped structure; in the second extending state, a bending amplitude of the second extending sections is smaller than that in the first extending state, and the second extending sections are suitable for passing through the magnetic ring.

20. An electric drive assembly, comprising:
a drive motor;
a motor controller including a power assembly, wherein the power assembly includes a circuit board and a plurality of induction elements arranged on the circuit board; and
a terminal connector including a mounting part, a terminal block and a plurality of magnetic conductors, the terminal block being arranged on the mounting part and including a plurality of connecting terminals, each connecting terminal including a first connecting end and a second connecting end, the plurality of magnetic conductors being arranged on the mounting part and in one-to-one correspondence with the plurality of connecting terminals, each magnetic conductor having a first coupling space and a second coupling space, the connecting terminal passing through a corresponding first coupling space, the first connecting end and the second connecting end respectively extending out of the mounting part, and the plurality of second coupling spaces being arranged in correspondence with the plurality of induction elements and located on an outer side of the mounting part;
wherein the power assembly is electrically connected to the drive motor through the terminal block, the induction elements extend into corresponding second coupling spaces, and meanwhile, an induced magnetic field generated by the connecting terminal acts on the induction element through the magnetic conductor.
